(19) United States
(12) Patent Application Publication
(10) Pub. No.: US 2008/0076236 A1
(43) Pub. Date: Mar. 27, 2008

(54) METHOD FOR FORMING SILICON-GERMANIUM EPITAXIAL LAYER

(76) Inventors: Jih-Shun Chiang, Changhua County (TW); Hung-Lin Shih, Hsinchu City (TW); Li-Yuen Tang, Hsinchu County (TW); Tian-Fu Chiang, Taipei City (TW); Ming-Chi Fan, Hsinchu City (TW); Chin-I Liao, Tainan City (TW); Chin-Cheng Chien, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,739

(22) Filed: Sep. 21, 2006

(51) Int. Cl. H01L 21/20; H01L 33/00; H01L 21/36

(52) U.S. Cl. 438/509

(57) ABSTRACT

A method for forming a SiGe epitaxial layer is described. A first SEG process is performed under a first condition, consuming about 1% to 20% of the total process time for forming the SiGe epitaxial layer. Then, a second SEG process is performed under a second condition, consuming about 99% to 80% of the total process time. The first condition and the second condition include different temperatures or pressures. The first and the second SEG processes each uses a reactant gas that includes at least a Si-containing gas and a Ge-containing gas.

### BACKGROUND OF THE INVENTION

1. Field of Invention

This invention relates to a method of forming a semiconductor structure. More particularly, this invention relates to a method for forming a silicon-germanium (SiGe) epitaxial layer using a selective epitaxy growth (SEG) method.

2. Description of Related Art

As the IC technology enters the deep sub-micron generations, the dimensions of semiconductor devices are greatly reduced increasing the operating speed effectively. As the device dimensions are further reduced, taking a MOS transistor as an example, the parasitic capacitance and resistance of the gate and the source/drain region further increase. The performance improvement due to device miniaturization is thus limited. If the device dimensions continue to reduce, a majority of the lateral area is occupied by the ohmic contacts of the source/drain regions limiting the integration degree.

Currently, the selective epitaxy growth (SEG) technique is applied to form SiGe epitaxial layer in semiconductor processes to overcome the above-mentioned problems. Since the radius of a germanium atom is greater than that of a silicon atom, the entire lattice becomes strained when a silicon atom therein is replaced by a germanium atom. With the same carrier density, the electron mobility and the hole mobility are increased by about 5 times and 10 times, respectively, for strained silicon or SiGe, as compared with single-crystal silicon. The device resistance is thus lowered, and the integration degree continues to increase for the development of next generation products.

However, the uniformity of a SiGe layer is usually undesirable in the prior art, which leads to the problem of pattern loading effect so that the subsequent process is difficult to control, adversely affecting the yield. Moreover, if the SEG process for forming the SiGe epitaxial layer is not properly controlled, the SiGe epitaxial layer may grow at unassigned locations, which means a small selectivity window. Furthermore, a low growth rate for the SiGe epitaxial layer or a low throughput may occur. More seriously, the interface of the insulating spacer of the MOS transistor may be damaged.

Accordingly, it is important to form a SiGe layer with desirable uniformity and high throughput simultaneously while preserving the interface of the insulating spacer.

### SUMMARY OF THE INVENTION

This invention provides a method for forming a SiGe epitaxial layer, wherein the uniformity of the SiGe epitaxial layer is kept while the throughput is enhanced.

This invention also provides a method for forming a SiGe epitaxial layer, which utilizes a high-temperature SEG process and a low-temperature SEG process.

In a method for forming a SiGe epitaxial layer of this invention, a first SEG process is performed under a first condition, consuming about 1% to 20% of the total process time for forming the SiGe epitaxial layer. A second SEG process is then performed under a second condition, consuming about 99% to 80% of the total process time. The first condition and the second condition include different temperatures or pressures. The first and the second SEG processes each uses a reactant gas that includes at least a Si-containing gas and a Ge-containing gas.

According to one embodiment of the above method, the first condition includes a relatively higher pressure and the second condition a relatively lower pressure. The relatively higher pressure may be about 10 Torr or higher, while the relatively lower pressure may be about 5 Torr or lower.

According to one embodiment of the above method, the first condition includes a relatively higher temperature and the second condition a relatively lower temperature.

According to one embodiment of the above method, the relatively higher temperature is about 700-900° C., while the relatively lower one is about 500-700° C.

According to one embodiment of the above method, before performing the first SEG process, a pre-annealing process is conducted. After the pre-annealing process and before the first SEG process, a pad layer may be formed on the substrate.

According to one embodiment of the above method, the reactant gas further includes a hydrogen chloride gas, possibly in a flow rate of about 50-200 sccm.

According to one embodiment of the above method, the Si-containing gas may include silane, disilane or dichlorosilane, possibly in a flow rate of about 50-500 sccm.

According to one embodiment of the above method, the Ge-containing gas may include germane, possibly in a flow rate of about 100-300 sccm.

According to one embodiment of the above method, the substrate beside the gate structure further includes a cavity, in which the SiGe epitaxial layer is formed.

According to one embodiment of the above method, the SiGe epitaxial layer serves as a source/drain of a PMOS transistor.

In another method for forming a SiGe epitaxial layer of this invention, a high-temperature SEG process is performed to form a lower SiGe sub-layer with a thickness of about 23% to 50% of the predetermined overall thickness of the SiGe epitaxial layer. A low-temperature SEG process is then performed to form an upper SiGe sub-layer with a thickness of about 77% to 50% of the predetermined overall thickness. The high-temperature and the low-temperature SEG processes each uses a reactant gas that includes at least a Si-containing gas and a Ge-containing gas.

According to one embodiment of the above method, the high-temperature SEG is conducted at about 700-900° C., while the low-temperature SEG at about 500-700° C.

According to one embodiment of the above method, a pre-annealing process is conducted before the high-temperature SEG process. After the pre-annealing process and before the high-temperature SEG, a pad layer may be formed on the substrate.

According to one embodiment of the above method, the reactant gas further includes a hydrogen chloride gas, possibly in a flow rate of about 50-200 sccm.

According to one embodiment of the above method, the silicon-containing gas includes silane, disilane or dichlorosilane, possibly in a flow rate of about 50-500 sccm.

According to one embodiment of the above method, the Ge-containing gas includes germane, possibly in a flow rate of about 100-300 sccm.

According to one embodiment of the above method, the substrate at both sides of a gate structure further includes a cavity, in which the SiGe epitaxial layer is formed.

According to one embodiment of the above method, the SiGe epitaxial layer serves as a source/drain of a PMOS transistor.

The formation of the SiGe epitaxial layer of this invention relies on both a high-temperature SEG process and a low-temperature SEG process, or relies on both a high-pressure SEG process and a low-pressure SEG process. Consequently, not only the uniformity of the SiGe layer is improved increasing the yield, but also the epitaxy growth rate is increased resulting in a high throughput.

It is to be understood that both the foregoing general description and the following detailed description are exemplary, and are intended to provide further explanation of the invention as claimed.

### BRIEF DESCRIPTION OF THE DRAWINGS

FIG. 1 is a flow chart of steps in exemplary processes that may be used in the formation of a SiGe epitaxial layer according to one embodiment of this invention.

FIGS. 2A to 2B are cross-sectional views showing selected process steps for forming a SiGe epitaxial layer according to one embodiment of this invention.

FIG. 3 is a cross-section view showing an alternative step for the formation of a SiGe epitaxial layer according to another embodiment of this invention.

FIG. 4 is a flow chart of steps in exemplary processes that may be used in forming a SiGe epitaxial layer according to still another embodiment of this invention.

### DESCRIPTION OF THE PREFERRED EMBODIMENTS

### First Embodiment

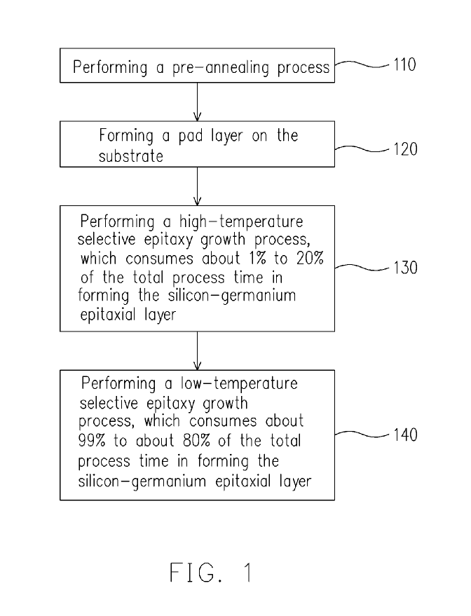

FIG. 1 is a flow chart of steps in exemplary processes that may be used in the formation of a SiGe layer according to one embodiment of this invention.

Referring to FIG. 1, in Step 110, a pre-annealing process is performed possibly at about 800° C. A pad layer is then formed on the substrate (Step 120). The pad layer and the substrate are formed with a similar material, such as, silicon.

Then, a high-temperature SEG process is conducted, consuming about 1% to 20% of the total process time for forming the entire SiGe epitaxial layer. In one embodiment, the high-temperature SEG process consumes about 1% to 15%, preferably about 1% to 10% and more preferably about 3% to 6%, of the total process time. In one embodiment, the high-temperature SEG process is conducted for about 30 seconds.

The high-temperature SEG process is performed at about 700-900° C., preferably about 750-850° C. and more preferably about 780° C.

In the above high-temperature SEG process, the reactant gas includes at least a Si-containing gas and a Ge-containing gas. The Si-containing gas may include silane, disilane or dichlorosilane, in a flow rate of about 50-500 sccm, preferably about 80-150 sccm. The Ge-containing gas may include germane, in a flow rate of about 100-300 sccm, preferably about 130-180 sccm.

Further, the reactant gas can also include a hydrogen chloride gas to enhance the uniformity of the epitaxial layer and lower the loading effect. The flow rate of the hydrogen chloride gas may be about 50-200 sccm, preferably about 110-150 sccm.

Aftet this, a low-temperature SEG process is performed in step 140, consuming about 99% to 80% of the total process time for forming the entire SiGe epitaxial layer. In one embodiment, the low-temperature SEG process consumes about 99% to 85%, preferably about 99% to 90% and more preferably about 97% to 94%, of the total process time, and may be conducted for about 700-800 seconds.

The low-temperature SEG process is conducted at about 500-700° C., preferably about 600° C. to 700° C. and more preferably about 650°.

The reactant gas for the low-temperature SEG process includes at least a Si-containing gas and a Ge-containing gas. The Si-containing gas may include silane, disilane or dichlorosilane, in a flow rate of about 50-500 sccm, preferably about 80-150 sccm. The Ge-containing gas may include germane, in a flow rate of about 100-300 sccm, preferably about 130-180 sccm.

The reactant gas can further include a hydrogen chloride gas to enhance the uniformity of the epitaxial layer and lower the loading effect. The flow rate of the hydrogen chloride gas may be about 50-200 sccm, preferably about 110-150 sccm.

It is particularly noted that the high-temperature SEG process and the low-temperature SEG process can use the same reactant gas or different reactant gases.

It is also noted that the pre-annealing process (Step 110) and the step of forming a pad layer (Step 120) are optional according to the process requirements.

The above Steps 130 and 140 are specified based on the process time of the SEG process. In another embodiment, the two SEG processes are specified based on the thickness of the epitaxial layer formed. Specifically, a high-temperature SEG process is performed to form a lower part of the SiGe epitaxial layer with a thickness of about 23% to 50% of the overall thickness of the same. A low-temperature SEG process is then performed to form an upper part of the SiGe epitaxial layer with a thickness of about 77% to 50% of the overall thickness of the same.

In the above method for forming a SiGe epitaxial layer, a high-temperature SEG process is performed to form the lower part of the same over a substrate, followed by a low-temperature SEG process for forming the upper part of the same. As a result, the selectivity window of the SEG process is increased, and the throughput of the process is also improved. Moreover, the above method of this invention can preserve a good interface for the insulating spacer, while the uniformity of the SiGe layer is maintained lowering the pattern loading effect.

### Second Embodiment

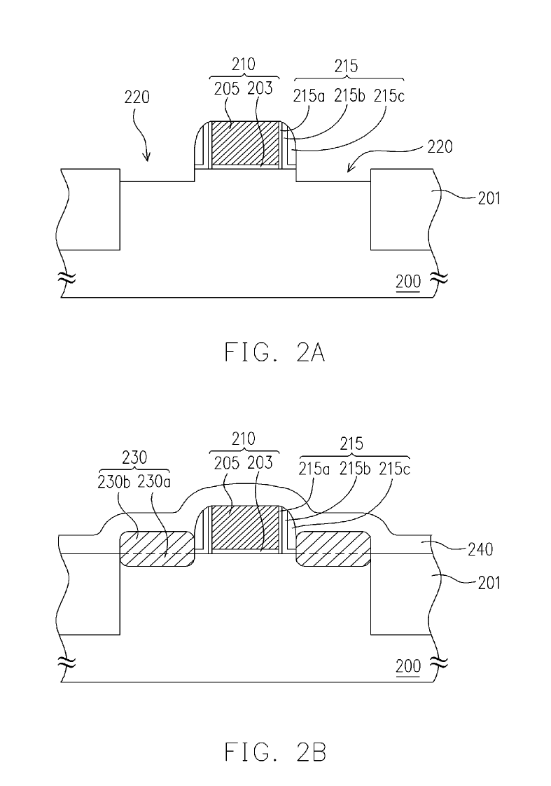

FIGS. 2A and 2B are cross-sectional views showing selected process steps for forming a SiGe epitaxial layer according to one embodiment of this invention.

Referring to FIG. 2A, the method for forming a SiGe layer of this invention is applied to the process of a PMOS transistor. An isolation structure 201 is formed in the substrate 200 and a gate structure 210 is formed on the substrate 200, wherein the substrate 200 is, for example, a silicon substrate. The isolation structure 201 includes a shallow trench isolation structure formed with silicon oxide. The gate structure 210 includes, from top to bottom, a gate dielectric layer 203 and a gate electrode 205. The material of the gate dielectric layer 203 may include silicon oxide, while that of the gate electrode 204 may include doped polysilicon, metal, metal silicide or other conductive material. The SiGe epitaxial layer is expected to form above the substrate 200 at both sides of the gate structure 210.

In one embodiment, the sidewall of the gate structure 210 is formed with an insulating spacer 215 thereon, which may be a single layer of an insulating material like silicon oxide, or be a multi-layered insulator. In an embodiment, the insulating spacer 25 includes, starting from the sidewall of the gate structure 210, a silicon oxide layer 215a, a silicon nitride layer 215b and a silicon oxide layer 215c, as shown in FIG. 2A.

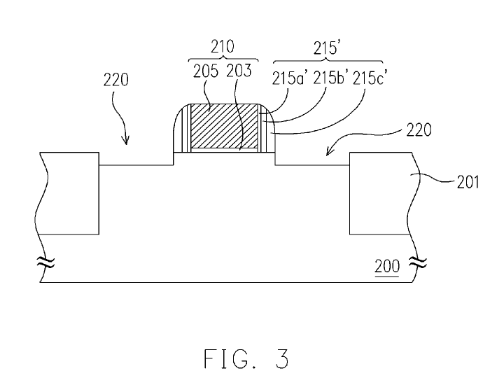

Referring to FIG. 3, the insulating spacer 215 may alternatively be configured with a silicon oxide layer 215a′, a silicon oxide layer 215b′ and a silicon nitride layer 215c′ in another embodiment.

After forming the gate structure 210, a cavity 220 is formed in the substrate 200 beside the gate structure 205, as shown in FIG. 2A.

A pre-annealing process is then performed, possibly at about 800° C. for about 120 seconds. A pad layer (not shown) is then formed on the substrate, wherein the pad layer and the substrate 200 can be formed with the same material, for example, silicon. The pad layer is formed through CVD for about 20-30 seconds.

However, the pre-annealing process and the step of forming the pad layer are optional, depending on the requirements of the process.

Referring to FIG. 2B, a high-temperature SEG process is performed at about 700-900° C., preferably about 750-850° C. and more preferably about 780° C. The high-temperature SEG process may be conducted for about 30 second. The lower SiGe sub-layer 230a formed in the high-temperature SEG process has a thickness of about 23% to 50% of the predetermined overall thickness of the SiGe layer. In one embodiment, the lower SiGe sub-layer 230a is about 300 to 600 angstroms thick, for example.

In the high-temperature SEG process, the reactant gas includes at least a Si-containing gas and a Ge-containing gas. In an embodiment, the Si-containing gas may include silane, disilane or dichlorosilane, in a flow rate of about 50-500 sccm, preferably about 80-150 sccm. The Ge-containing gas may include germane, in a flow rate of about 100-300 sccm, preferably about 130-180 sccm.

The reactant gas may further include a hydrogen chloride gas to enhance the uniformity of the epitaxial layer and lower the loading effect, which may have a flow rate of about 50-200 sccm, preferably about 110-150 sccm.

In one embodiment, the Si-containing gas used in the high-temperature SEG process includes dichlorosilane in a flow rate of about 120 sccm. The Ge-containing gas includes germane in a flow rate is about 160 sccm. The flow rate of the hydrogen chloride gas is about 140 sccm. The pressure is about 15 Torr, for example.

Still referring to FIG. 2B, a low-temperature SEG process is performed at about 500-700° C., preferably about 600-700° C. and more preferably about 650° C., to form an upper SiGe sub-layer 230b with a thickness of about 77% to 50% of the predetermined overall thickness of the SiGe epitaxial layer. In one embodiment, the upper SiGe sub-layer 203b may be about 600-1000 angstroms thick. The SiGe epitaxial layer 230 including the sub-layers 230a and 230b has an overall thickness of about 1200-1300 angstroms. The low-temperature SEG may be conducted for about 700-800 seconds.

The reactant gas used in the low-temperature SEG process includes at least a Si-containing gas and a Ge-containing gas. In some cases, the Si-containing gas includes silane, disilane or dichlorosilane in a flow rate of about 50-500 sccm, preferably about 80-150 sccm. The Ge-containing gas includes germane in a flow rate of about 100-300 sccm, preferably about 130-180 sccm.

The reactant gas may further include a hydrogen chloride gas to enhance the uniformity of the epitaxial layer and lower the loading effect. The flow rate of the hydrogen chloride gas may be about 50-200 sccm, preferably about 110-150 sccm.

In one embodiment, the Si-containing gas is silane in a flow rate of about 136 sccm, and the Ge-containing gas is germane in a flow rate of about 265 sccm. The flow rate of the HCl gas is about 115 sccm. The pressure is about 10 Torr.

The above SEG processes are specified by the thickness of the SiGe sub-layer formed. In another embodiment, the above SEG processes may be specified by the process time. Similar to the first embodiment, the high-temperature SEG consumes about 1% to 20% of the total process time for forming the entire SiGe epitaxial layer, while the low-temperature SEG process consumes about 99% to 80% of the same.

The overall process time for forming the entire SiGe epitaxial layer is related to the predetermined thickness. With the introduction of processes of new generations, the thicknesses of the SiGe epitaxial layer 230 and the sub-layers 230a and 230b each can be varied according to the design and requirements of the device.

Further, it is also noted that the high-temperature SEG process and the low-temperature SEG process can use the same reactant gas or different reactant gases.

After forming the SiGe epitaxial layer 230, the SiGe epitaxial layer 230 can be doped with a P-dopant like boron or indium to form a PMOS transistor. An etch-stop layer 240 may be further formed on the substrate 200, possibly including silicon nitride and formed through CVD, for the subsequent contact opening etching. The etch-stop layer 240 may have a high compressive stress to raise the driving current of the PMOS.

Since the high-temperature SEG process has a larger selectivity window and higher growth rate, the lower SiGe sub-layer 230a is formed rapidly increasing the throughput. Furthermore, the high-temperature SEG process can prevent the interface of the insulation spacer 215 from being damaged.

Moreover, since the upper SiGe sub-layer 230b is formed with low-temperature SEG, the uniformity of the SiGe epitaxial layer 230 is improved reducing the pattern loading effect. Thus, the later processes are controlled more easily improving the yield.

### Third Embodiment

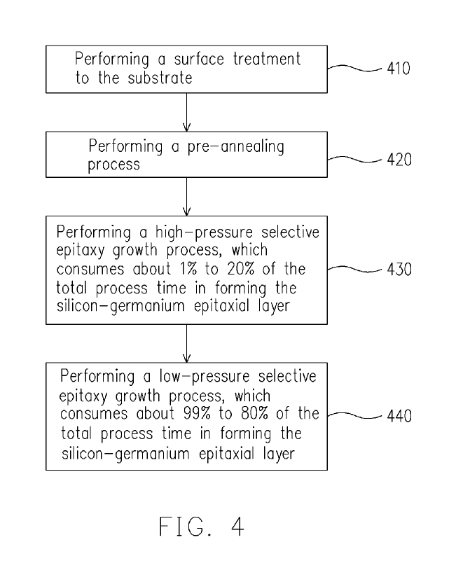

FIG. 4 is a flow chart of steps in exemplary processes that may be used in forming a SiGe epitaxial layer according to still another embodiment of this invention.

Referring to FIG. 4, a surface treatment is performed to the substrate in Step 410, possibly being a pre-cleaning or gas diffusion treatment. A pre-annealing process is then conducted in Step 420, possibly at a temperature of about 800° C.

In next step (430), a high-pressure SEG process is performed, consuming about 1% to 20%, preferably about 8% to 17%, of the total process time for forming the entire SiGe epitaxial layer.

The high-pressure SEG process may be performed under a pressure of about 10 Torr or higher at about 650° C. The reactant gas used includes at least a Si-containing gas and a Ge-containing gas. The Si-containing gas may include silane, disilane or dichlorosilane in a flow rate of about 50-500 sccm, preferably about 50-150 sccm. The Ge-containing gas may be germane in a flow rate of about 100-300 sccm, preferably about 150-250 sccm.

The reactant gas can also include a hydrogen chloride gas, which may have a flow rate of about 50-200 sccm, preferably about 100-200 sccm.

In next step (440), a low-pressure SEG process is performed, which consumes about 99% to 80%, preferably about 92% to 83%, of the total process time.

The low-pressure SEG process may be performed under a pressure of about 5 Torr or lower at about 650° C. The reactant gas used includes at least a Si-containing gas and a Ge-containing gas. The Si-containing gas may include silane, disilane or dichlorosilane in a flow rate of about 50-500 sccm, preferably about 50-150 sccm. The Ge-containing gas may be germane in a flow rate of about 100-300 sccm, preferably about 150-250 sccm.

The reactant gas used in the low-pressure SEG may also include an HCl gas, which may have a flow rate of about 50-200 sccm, preferably about 100-200 sccm.

In an embodiment, the high-pressure SEG process forms a SiGe epitaxial layer of 100-200 angstroms thick, while the low-pressure one forms a SiGe epitaxial layer of 1000-1100 angstroms thick.

Because the high-pressure SEG process has a large selectivity window and has a lower sensitivity to the quality of the surface for epitaxy, a lower SiGe sub-layer is formed rapidly. In addition, the subsequent low-pressure SEG process can reduce the pattern loading effect and thereby improve the uniformity of the SiGe epitaxial layer.

The cross-sectional view of the SiGe epitaxial layer formed in this embodiment is similar to that shown in FIGS. 2A, 2B and 3. In addition, the method provided in this embodiment can also be applied to other processes required to form SiGe epitaxial layers except to a PMOS fabricating process.

It is also noted that in an embodiment where the substrate surface is clean, a low-pressure SEG process can be directly performed, possibly under a pressure of about 5 Torr or lower, to form a SiGe epitaxial layer. This method can also reduce the pattern loading effect.

It will be apparent to those skilled in the art that various modifications and variations can be made to the structure of this invention without departing from the scope or spirit of the invention. In view of the foregoing descriptions, it is intended that this invention covers modifications and variations of this invention if they fall within the scope of the following claims and their equivalents.

What is claimed is:

1. A method for forming a SiGe epitaxial layer, comprising:
performing a first selective epitaxy growth (SEG) process under a first condition, which consumes about 1% to 20% of a total process time for forming the SiGe epitaxial layer; and performing a second SEG process under a second condition, which consumes about 99% to 80% of the total process time,
wherein the first condition and the second condition include different temperatures or different pressures, and the first and the second SEG processes each uses a reactant gas that comprises at least a Si-containing gas and a Ge-containing gas.

2. The method of claim 1, wherein the first condition includes a relatively higher pressure and the second condition includes a relatively lower pressure.

3. The method of claim 2, wherein the relatively higher pressure is about 10 Torr or higher.

4. The method of claim 2, wherein the relatively lower pressure is about 5 Torr or lower.

5. The method of claim 1, wherein the first condition includes a relatively higher temperature and the second condition includes a relatively lower temperature.

6. The method of claim 5, wherein the relatively higher temperature is about 700-900° C.

7. The method of claim 5, wherein the relatively lower temperature is about 500-700° C.

8. The method of claim 5, further comprising performing a pre-annealing process before the first SEG process.

9. The method of claim 5, wherein after the pre-annealing process and before the first SEG process, a pad layer is formed on the substrate.

10. The method of claim 1, wherein the reactant gas further comprises a hydrogen chloride gas.

11. The method of claim 10, wherein a flow rate of the hydrogen chloride gas is about 50-200 sccm.

12. The method of claim 1, wherein the Si-containing gas is selected from the group consisting of silane, disilane and dichlorosilane.

13. The method of claim 1, wherein a flow rate of the Si-containing gas is about 50-500 sccm.

14. The method of claim 1, wherein the Ge-containing gas comprises germane.

15. The method of claim 1, wherein a flow rate of the Ge-containing gas is about 100-300 sccm.

16. The method of claim 1, wherein the substrate comprises a cavity, and the SiGe epitaxial layer is formed in the cavity.

17. The method of claim 1, wherein the SiGe epitaxial layer serves as a source/drain of a PMOS transistor.

18. A method for forming a SiGe epitaxial layer, comprising:
performing a high-temperature selective epitaxy growth (SEG) process to form a lower SiGe sub-layer, which has a thickness of about 23% to 50% of an overall thickness of the SiGe epitaxial layer; and
performing a low-temperature SEG process to form an upper SiGe sub-layer, which has a thickness of about 77%-50% of the overall thickness of the SiGe epitaxial layer, wherein the high-temperature and the low-temperature SEG processes each uses a reactant gas that comprises at least a Si-containing gas and a Ge-containing gas.

19. The method of claim 18, wherein the high-temperature SEG process is conducted at about 700-900° C.

20. The method of claim 18, wherein the low-temperature SEG process is conducted at about 500-700° C.

21. The method of claim 18, further comprising performing a pre-annealing process before the high-temperature SEG process.

22. The method of claim 21, wherein after the pre-annealing process and before the high-temperature SEG process, a pad layer is further formed on the substrate.

23. The method of claim 18, wherein the reactant gas further comprises a hydrogen chloride gas.

24. The method of claim 23, wherein a flow rate of the hydrogen chloride gas is about 50-200 sccm.

25. The method of claim 18, wherein the Si-containing gas is selected from the group consisting of silane, disilane and dichlorosilane.

26. The method of claim 18, wherein a flow rate of the Si-containing gas is about 50-500 sccm.

27. The method of claim 18, wherein the Ge-containing gas comprises germane.

28. The method of claim 18, wherein a flow rate of the Ge-containing gas is about 100-300 sccm.

29. The method of claim 18, wherein the substrate further comprise a cavity, and the SiGe epitaxial layer is formed in the cavity.

30. The method of claim 18, wherein the SiGe epitaxial layer serves as a source/drain of a PMOS transistor.
